(19) United States
(12) Patent Application Publication
(10) Pub. No.: US 2026/0136809 A1
(43) Pub. Date: May 14, 2026

(54) Display Apparatus Having a Light-Emitting Device and a Pixel Lens

(71) Applicant: LG Display Co., Ltd., Seoul (KR)

(72) Inventors: Myung Eun Song, Paju-si (KR); Su Jeong Lee, Paju-si (KR); Ji Eun Lee, Paju-si (KR)

(21) Appl. No.: 19/326,070

(22) Filed: Sep. 11, 2025

(30) Foreign Application Priority Data
Nov. 12, 2024 (KR) 10-2024-0160317

(51) Int. Cl. H10K 59/80

(52) U.S. Cl. CPC H10K 59/873; H10K 59/879

(57) ABSTRACT

A display apparatus including a light-emitting device and a pixel lens is provided. The light-emitting device can be covered by the optical insulating layer. A lens planarization layer can be disposed on the optical insulating layer. The pixel lens can be disposed between the optical insulating layer and the lens planarization layer. The pixel lens can be surrounded by a lens passivation layer. The lens passivation layer can block oxygen and moisture moving toward the pixel lens. Thus, in the display apparatus, the deterioration in the quality of the image provided to a user due to oxygen and/or moisture can be prevented.

### CROSS-REFERENCE TO RELATED APPLICATION

This application claims the benefit of Republic of Korea Patent Application No. 10-2024-0160317, filed on Nov. 12, 2024, which is hereby incorporated by reference in its entirety.

### BACKGROUND

### Field of Technology

The present disclosure relates to a display apparatus in which a light-emitting device and a pixel lens are stacked on each emission area.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit disposed between a first electrode and a second electrode.

Light emitted from each light-emitting device can be focused by one pixel lens among pixel lenses. For example, each of the pixel lenses can overlap one of the light-emitting devices. The pixel lenses can be disposed between an optical insulating layer disposed on the light-emitting devices and a lens planarization layer disposed on the optical insulating layer. Thus, in the display apparatus, an optical distance of light emitted from each light-emitting device can be sufficiently secured by the optical insulating layer. And, in the display apparatus, the deformation of the pixel lenses due to external impact can be prevented by the lens planarization layer.

### SUMMARY

Accordingly, the present disclosure is directed to a display apparatus that substantially obviates one or more problems due to limitations and disadvantages of the related art.

An object of the present disclosure is to provide a display apparatus capable of preventing or at least reducing the deterioration in the quality of the image provided to the user.

Another object of the present disclosure is to provide a display apparatus capable of preventing or at least reducing the denaturation of the pixel lens due to oxygen and/or moisture.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising: a light-emitting device on an emission area of a device substrate; an optical insulating layer on the light-emitting device, the optical insulating layer extending beyond the emission area; a lens passivation layer including a lower passivation layer on the optical insulating layer and an upper passivation layer on the lower passivation layer; a pixel lens between the lower passivation layer and the upper passivation layer of the lens passivation layer, the pixel lens overlapping with the emission area; and a lens planarization layer on the upper passivation layer of the lens passivation layer, the lens planarization layer including a region overlapping with the emission area, wherein the lens passivation layer has an oxygen gas transmission rate (OTR) that is less than an OTR of the optical insulating layer and an OTR of the lens planarization layer.

In one embodiment, a display apparatus comprises: a first light-emitting device on a first emission area of a device substrate; a second light-emitting device on a second emission area of the device substrate; an optical insulating layer on the first light-emitting device and the second light-emitting device; a first pixel lens on the optical insulating layer, the first pixel lens overlapping with the first emission area; a first lens passivation layer on the optical insulating layer, the first lens passivation layer surrounding the first pixel lens; a second pixel lens on the optical insulating layer, the second pixel lens overlapping with the second emission area; a second lens passivation layer on the optical insulating layer, the second lens passivation layer surrounding the second pixel lens; and a lens planarization layer on the first lens passivation layer and the second lens passivation layer, the lens planarization layer overlapping with the first emission area and the second emission area, wherein the first lens passivation layer and the second lens passivation layer have a water vapor transmission rate (WVTR) that is less than a WVTR of the optical insulating layer and a WVTR of the lens planarization layer.

In one embodiment, a display device comprises: a substrate including an emission area; a thin film transistor on the substrate; a light emitting device that is connected to the thin film transistor, the light emitting device in the emission area; a first lens passivation layer over the light emitting device; a pixel lens on the first lens passivation layer and overlapping the light emitting device in the emission area, pixel lens having a curved upper surface; and a second lens passivation layer that covers the curved upper surface of the pixel lens, the second lens passivation layer having an upper surface and a lower surface that each have a curved shape that corresponds to the curved upper surface of the pixel lens.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to an embodiment of the present disclosure;

FIG. 3 is an enlarged view of K1 region in FIG. 1 according to an embodiment of the present disclosure;

FIG. 4 is a view showing a cross-section taken along line I-I′ of FIG. 3 according to an embodiment of the present disclosure; and

FIGS. 5 to 14 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

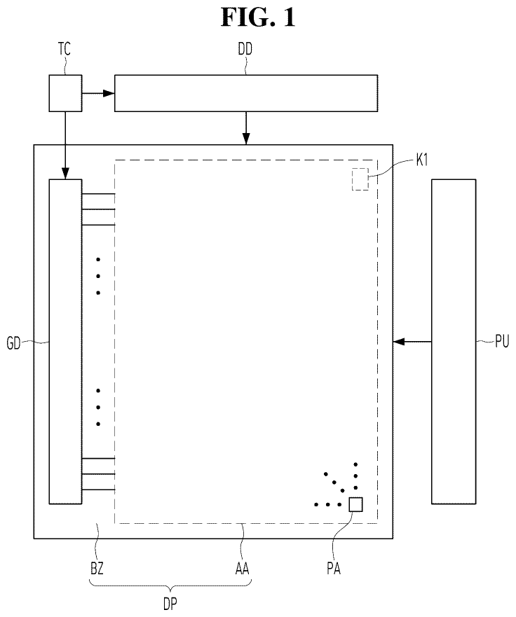

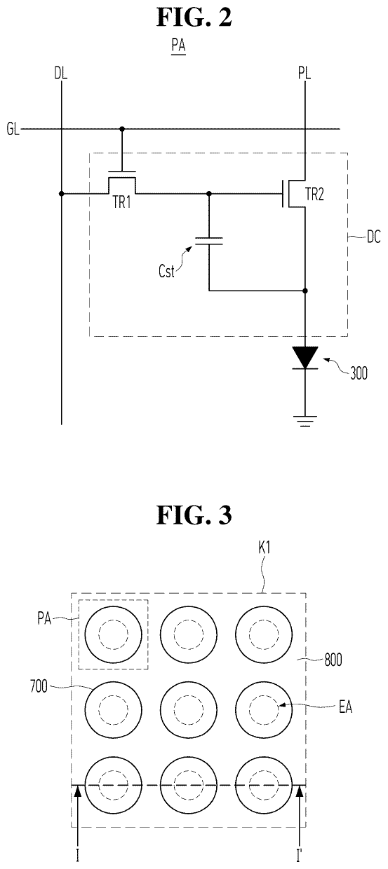

FIG. 1 is a view schematically showing a display apparatus according to an embodiment of the present disclosure. FIG. 2 is a view showing a circuit of a pixel area in the display apparatus according to an embodiment of the present disclosure.

Referring to FIGS. 1 and 2, the display apparatus according to the embodiment of the present disclosure can include a display panel DP. The display panel DP can generate an image provided to a user. For example, the display panel DP can include pixel areas PA. Various signals can be applied in each pixel area PA through signal wirings GL, DL and PL. The signal wirings GL, DL and PL can include a gate line GL applying a gate signal, a data line DL applying a data signal, and a power voltage supply line PL supplying a power voltage.

The gate line GL can be electrically connected to a gate driver GD. The data line DL can be electrically connected to a data driver DD. The gate driver GD and the data driver DD can be electrically connected to a timing controller TC. For example, the gate driver GD and the data driver DD can be controlled by the timing controller TC. The power voltage supply line PL can be electrically connected to a power unit PU.

The display panel DP can include an active area AA and a bezel area BZ disposed outside the active area AA. The pixel areas PA can be disposed within the active area AA. For example, the pixel areas PA can be surrounded by the bezel area BZ. The gate driver GD, the data driver DD, the timing controller TC and the power unit PU can be disposed outside the active area AA. At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color according to a signal applied through the signal wirings GL, DL and PL. For example, a driving circuit DC electrically connected to the signal wirings GL, DL and PL, and a light-emitting device 300 electrically connected to the driving circuit DC can be disposed in each pixel area PA.

The driving circuit DC can control the light-emitting device 300 according to a signal applied to the signal wirings GL, DL and PL. For example, the driving circuit DC can apply a driving current corresponding to the data signal to the light-emitting device 300 according to the gate signal using the power voltage. The driving current applied to the light-emitting device 300 by the driving circuit DC can be maintained for one frame. For example, the driving circuit DC can include a first thin film transistor TR1, a second thin film transistor TR2 and a storage capacitor Cst.

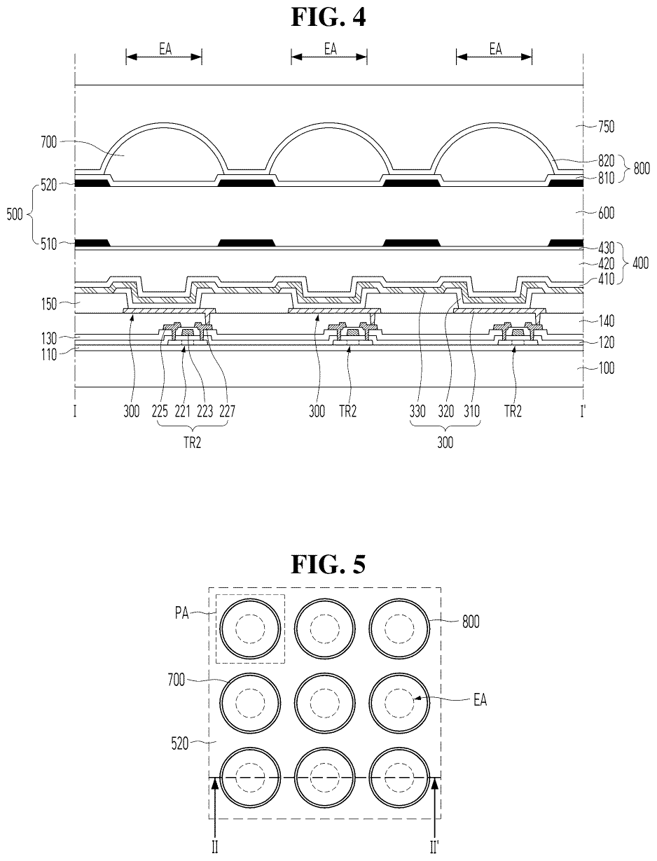

FIG. 3 is an enlarged view of K region in FIG. 1 according to one embodiment. FIG. 4 is a view showing a cross-section taken along line I-I′ of FIG. 3 according to one embodiment.

Referring to FIGS. 2 to 4, the first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a channel region and a source region. The channel region can be disposed between the drain region and the source region. The drain region and the source region can have an electrical conductivity greater than the channel region. A resistance of the drain region and a resistance of the source region can have a smaller than a resistance of the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can be electrically connected to the drain region of the second semiconductor pattern 221. The second drain electrode 225 can be insulated from the second gate electrode 223. The second drain electrode 225 can include a different material from the second gate electrode 223. For example, the second drain electrode 225 can be disposed on a different layer from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can be electrically connected to the source region of the second semiconductor pattern 221. The second source electrode 227 can be insulated from the second gate electrode 223. The second source electrode 227 can include a different material from the second gate electrode 223. For example, the second source electrode 227 can be disposed on a different layer from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. For example, the storage capacitor Cst can be electrically connected to the second gate electrode 223 and the second source electrode 227. The storage capacitor Cst can have a stacked structure of capacitor electrodes. For example, the storage capacitor Cst can have a structure in which a first capacitor electrode electrically connected to the second gate electrode 233 and a second capacitor electrode electrically connected to the second source electrode 227 are stacked. The storage capacitor Cst can be formed using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227.

The driving circuit DC of each pixel area PA can be supported by a device substrate 100. The device substrate 100 can include an insulating material. For example, the device substrate 100 can include glass or plastic. At least one insulating layers 110, 120, 130, 140 and 150 for preventing unnecessary electrical connection can be disposed on the device substrate 100. For example, a buffer insulating layer 110, a gate insulating layer 120, an interlayer insulating layer 130, a device planarization layer 140 and a bank insulating layer 150 can be disposed on the device substrate 100.

The buffer insulating layer 110 can be disposed on the device substrate 100. The buffer insulating layer 110 can prevent or at least reduce pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can be an inorganic insulating layer made of an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each pixel area PA may be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can be an inorganic insulating layer made of an inorganic insulating material.

The device planarization layer 140 can be disposed on the interlayer insulating layer 130. A thickness difference due to the driving circuit DC of each pixel area PA can be removed by the device planarization layer 140. For example, the first drain electrode, the first source electrode, the second drain electrode 225 and the second source electrode 227 of each pixel area PA can be covered by the device planarization layer 140. The device planarization layer 140 can include an insulating material. The device planarization layer 140 can include a material having a relative high fluidity. For example, the device planarization layer can be an organic insulating layer made of an organic insulating material. An upper surface of the device planarization layer 140 opposite to the device substrate 100 can be flat. For example, the upper surface of the device planarization layer 140 can be parallel to the upper surface of the device substrate 100.

The bank insulating layer 150 can be disposed on the device planarization layer 140. The bank insulating layer 150 can include an insulating material. For example, the bank insulating layer 150 can be an organic insulating layer made of an organic insulating material. The bank insulating layer 150 can include a different material from the device planarization layer 140. The bank insulating layer 150 can define an emission area EA in each pixel area PA. For example, a portion of the upper surface of the device planarization layer 140 overlapping with the emission area EA of each pixel area PA can be exposed by the bank insulating layer 150.

The light-emitting device 300 of each pixel area PA can emit light displaying a specific color. For example, the light-emitting device 300 of each pixel area PA can include a light-emitting unit 320 disposed between a first electrode 310 and a second electrode 330. The light-emitting device 300 of each pixel area PA can be disposed on the upper surface of the device planarization layer 140. The light-emitting device 300 of each pixel area PA can overlap the emission area EA defined in the corresponding pixel area PA by the bank insulating layer 150. For example, the first electrode 310, the light-emitting device 320 and the second electrode 330 of each pixel area PA can be sequentially stacked on a portion of the device planarization layer 140 of the corresponding pixel area PA exposed by the bank insulating layer 150.

The first electrode 310 can be disposed close to the device planarization layer 140. The first electrode 310 can include a conductive material. The first electrode 310 can include a material having relative high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 (e.g., a light emitting layer) can generate light having luminance corresponding to a voltage difference between the first electrode 310 and the second electrode 330. For example, the light-emitting unit 320 can include an emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

The second electrode 330 can include a conductive material. The second electrode 330 can include a different material from the first electrode 310. For example, a work-function of the second electrode 330 can be different from a work-function of the first electrode 310. The second electrode 330 can have a higher transmittance than the first electrode 310. For example, the second electrode 330 can be a transparent electrode made of a transparent conductive material, such as ITO and IZO. The light generated by the light-emitting unit 320 can be emitted outside through the second electrode 330.

A signal applied to the second electrode 330 of each pixel area PA can be a same as a signal applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. Thus, in the display apparatus according to the embodiment of the present disclosure, a process of forming the second electrode 330 in each pixel area PA can be simplified.

The light-emitting device 300 of each pixel area PA can be controlled independently from the light-emitting device 300 of adjacent pixel area PA. For example, the first electrode 310 of each pixel area PA can be spaced apart from the first electrode 310 of adjacent pixel area PA. The first electrode 310 of each pixel area PA can be insulated from the first electrode 310 of adjacent pixel area PA by the bank insulating layer 150. For example, an edge of the first electrode in each pixel area PA can be covered by the bank insulating layer 150.

The driving current generated by the driving circuit DC of each pixel area PA can be applied to the first electrode 310 of the corresponding pixel area PA. For example, the first electrode 310 of each pixel area PA can be in direct contact with the second source electrode 227 of the corresponding pixel area PA by penetrating the device planarization layer 140. A connection point between the first electrode 310 and the second source electrode 227 in each pixel area PA can overlap the bank insulating layer 150. For example, a portion of the first electrode 310 overlapping with the emission area EA in each pixel area PA can be in direct contact with the upper surface of the device planarization layer 140. Thus, in the display apparatus according to the embodiment of the present disclosure, the deviation in the location of the first electrode 310 in the emission area EA of each pixel area PA can be minimized. Therefore, in the display apparatus according to the embodiment of the present disclosure, the deviation in the luminance of the light emitted from the emission area EA of each pixel area PA due to the generating location can be prevented.

The emission area EA of each pixel area PA can realize a different color from the emission area EA of adjacent pixel area PA. For example, the emission area EA of each pixel area PA can be one of a blue emission area realizing a blue color, a green emission area realizing a green color, and a red emission area realizing a red color. The light emitted from the light-emitting device 300 of each pixel area PA can display a different color from the light emitted from the light-emitting device of adjacent pixel area PA. For example, the light-emitting unit 320 of each pixel area PA can generate blue light, green light or red light. The light-emitting unit 320 of each pixel area PA can be spaced apart from the light-emitting unit 320 of adjacent pixel area PA. For example, the light-emitting unit 320 of each pixel area PA can include an end disposed on the bank insulating layer 150.

An encapsulation structure 400 can be disposed on the light-emitting device 300 of each pixel area PA. The encapsulation structure 400 can prevent the damage of the light-emitting device 300 in each pixel area PA due to external moisture and impact. The light-emitting device 300 of each pixel area PA can be covered by the encapsulation structure 400. For example, a region disposed between the emission areas EA of the pixel areas PA can be defined as a non-emission area, and the encapsulation structure 400 can include a region overlapping with the emission area EA of each pixel area PA and a region overlapping with the non-emission area. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic insulating layer made of an inorganic insulating material, and the second encapsulating layer 420 can be an organic insulating layer made of an organic insulating material. A thickness difference due to the light-emitting device 300 of each pixel area PA can be removed by the second encapsulating layer 420. For example, an upper surface of the encapsulation structure 400 opposite to the device substrate 100 can be flat.

A barrier structure 500 can be disposed on the encapsulation structure 400. The barrier structure 500 can limit a travelling direction of the light emitted from the light-emitting device 300 of each pixel area PA. The barrier structure 500 can have a multi-layer structure. For example, the barrier structure 500 can have a stacked structure of a lower barrier pattern 510 and an upper barrier pattern 520 that is spaced apart from the lower barrier pattern 510.

The lower barrier pattern 510 can be disposed on the encapsulation structure 400. For example, a lower surface of the lower barrier pattern 510 toward the device substrate 100 can be in direct contact with the upper surface of the encapsulation structure 400. The lower barrier pattern can include a material capable of blocking light. For example, the lower barrier pattern 510 can include a black dye, such as carbon black. The lower barrier pattern 510 can be disposed outside the emission area EA defined in each pixel area PA. For example, the lower barrier pattern 510 can be disposed within the non-emission area. The lower barrier pattern 510 can overlap the bank insulating layer 150.

The upper barrier pattern 520 can be disposed on the lower barrier pattern 510. The upper barrier pattern 520 can be spaced apart from the lower barrier pattern 510. For example, an optical insulating layer 600 covering the lower barrier pattern 510 can be disposed on the encapsulation structure 400, and the upper barrier pattern 520 can be disposed on an upper surface of the optical insulating layer 600 opposite to the device substrate 100. Thus, the optical insulating layer 600 is between the lower barrier pattern 510 and the upper barrier pattern 520. The optical insulating layer 600 can include an insulating material. The optical insulating layer 600 can include a transparent material. For example, the optical insulating layer 600 can include an organic insulating material and/or an inorganic insulating material. The upper surface of the optical insulating layer 600 can be flat.

The optical insulating layer 600 can extend onto the emission area EA of each pixel area PA. For example, the optical insulating layer 600 can include a region overlapping with the emission area EA of each pixel area PA and a region overlapping with the non-emission area. The lower barrier pattern 510 can be covered by a region of the optical insulating layer 600 overlapping with the non-emission area. Thus, in the display apparatus according to the embodiment of the present disclosure, the light emitted from the light-emitting device 300 of each pixel area PA can be emitted by passing through the optical insulating layer 600. That is, in the display apparatus according to the embodiment of the present disclosure, the light emitted from the light-emitting device 300 of each pixel area PA can have an optical distance proportional to a thickness of the optical insulating layer 600. Therefore, in the display apparatus according to the embodiment of the present disclosure, an optical distance of the light emitted from the light-emitting device 300 of each pixel area PA can be sufficiently secured.

The upper barrier pattern 520 can include a material capable of blocking light. For example, the upper barrier pattern 520 can include a black dye, such as black carbon. The upper barrier pattern 520 can include a same material as the lower barrier pattern 510. The upper barrier pattern 520 can be disposed outside the emission area EA defined in each pixel area PA. For example, the upper barrier pattern 520 can be disposed within the non-emission area. A lower surface of the upper barrier pattern 520 toward the device substrate 100 can be in direct contact with the upper surface of the optical insulating layer 600. For example, a portion of the upper surface of the optical insulating layer 600 overlapping with the emission area EA of each pixel area PA can be exposed by the upper barrier pattern 520. The upper barrier pattern 520 can overlap the lower barrier pattern 510. For example, the upper barrier pattern 520 can have a planar shape same as the lower barrier pattern 510.

Pixel lenses 700 can be disposed on the portion of the upper surface of the optical insulating layer 600 exposed by the upper barrier pattern 520. Each of the pixel lenses 700 can overlap the emission area EA of one of the pixel areas PA. The light emitted from the light-emitting device 300 of each pixel area PA can be focused by one of the pixel lenses 700. For example, each of the pixel lenses 700 can function as a convex lens. Each of the pixel lenses 700 can be spaced apart from adjacent pixel lens 700. A lower surface (e.g., a first surface) of each pixel lens 700 toward the optical insulating layer 600 can be flat, and an upper surface (e.g., a second surface) of each pixel lens 700 opposite to the optical insulating layer 600 can have a convex shape. The pixel lens on each pixel area PA can have a larger size than the emission area EA defined in the corresponding pixel area PA. For example, an edge of each pixel lens 700 can overlap the upper barrier pattern 520. That is, an edge of each pixel lens 700 is on an upper surface of the upper barrier pattern 520. Thus, in the display apparatus according to the embodiment of the present disclosure, the light extraction efficiency of each pixel area PA can be improved.

The pixel lenses 700 can include a polymer material. For example, the pixel lenses 700 can include at least one of a polyester resin, an acrylic resin, a polyurethane resin, a melamine resin, a polyvinyl alcohol resin, and an oxazoline resin. Each of the pixel lenses 700 can be formed simultaneously with adjacent pixel lens 700. For example, a process of forming the pixel lenses 700 can include a step of forming a lens material layer on the upper barrier pattern 520 and the optical insulating layer 600, a step of forming lens patterns by removing a portion of the lens material layer overlapping with the non-emission area, and a step of forming the pixel lenses 700 by reflowing the lens patterns overlapping with the emission area EA.

A plane of the pixel lens 700 on each pixel area PA can have a shape corresponding to a plane of the emission area EA defined in the corresponding pixel area PA. For example, the emission area EA and the pixel lens 700 of each pixel area PA can have a plane of circular shape. Thus, in the display apparatus according to the embodiment of the present disclosure, the light emitted from the emission area EA of each pixel area PA can be focused uniformly.

A lens planarization layer 750 can be disposed on the pixel lenses 700. The lens planarization layer 750 can prevent or at least reduce the damage of the pixel lenses 700 due to the external impact. Each of the pixel lenses 700 can be completely covered by the lens planarization layer 750. For example, the lens planarization layer 750 can extend beyond the emission area EA defined in each pixel area PA. The lens planarization layer 750 can include an insulating material. The lens planarization layer 750 can include a transparent material. A refractive index of the lens planarization layer 750 can be smaller than a refractive index of each pixel lens 700. For example, the lens planarization layer 750 can include an organic insulating material and/or an inorganic insulating material. An upper surface of the lens planarization layer 750 opposite to the device substrate 100 can be flat.

Each of the pixel lenses 700 can be surrounded by a lens passivation layer 800. For example, the lens passivation layer 800 can include a lower passivation layer 810 and an upper passivation layer 820, which are sequentially stacked between the optical insulating layer 600 and the lens planarization layer 750, and each of the pixel lenses 700 can be disposed between the lower passivation layer 810 and the upper passivation layer 820. Thus, the lower passivation layer 810 is disposed on the optical insulating layer 600, the pixel lenses 700 are on the lower passivation layer 810 and contact an upper surface of the lower passivation layer, and an upper passivation layer 820 is on upper surfaces of the pixel lenses 800 and is in contact with the upper surfaces of the pixel lenses 700, for example. In one embodiment, the lower passivation layer 810 is in direct contact with the lower surface of a pixel lens 700 and the upper passivation layer 820 is in direct contact with the curved upper surface of the pixel lens 700. The lower passivation layer 810 and the upper passivation layer 820 can have an oxygen gas transmission rate (OTR) that is smaller than (e.g., less than) the optical insulating layer 600 and the lens planarization layer 750. Thus, in the display apparatus according to the embodiment of the present disclosure, oxygen gas contained in the optical insulating layer 600 and/or the lens planarization layer 750 cannot pass through the lower passivation layer 810 and the upper passivation layer 820. Therefore, in the display apparatus according to the embodiment of the present disclosure, the penetration of the external oxygen into each pixel lens 700 can be prevented or at least reduced by the lens passivation layer 800.

And, the lower passivation layer 810 and the upper passivation layer 820 can have a moisture barrier property that is higher than the optical insulating layer 600 and the lens planarization layer 750. For example, the lower passivation layer 810 and the upper passivation layer 820 can have a water vapor transmission rate (WVTR) smaller than the optical insulating layer 600 and the lens planarization layer 750. Thus, in the display apparatus according to the embodiment of the present disclosure, moisture contained in the optical insulating layer 600 and/or the lens planarization layer 750 cannot pass through the lower passivation layer 810 and the upper passivation layer 820. Therefore, in the display apparatus according to the embodiment of the present disclosure, the penetration of the external moisture into each pixel lens 700 can be prevented by the lens passivation layer 800.

In general, radicals in an unstable state formed by photolysis of a polymer material react with phenols and the like, and oxygen and/or moisture participate in photolysis reaction of a polymer. For example, the pixel lenses 700 made of a polymer material can be denatured by the penetration of the external oxygen and/or the external moisture. Thus, in the display apparatus according to the embodiment of the present disclosure, the denaturation of each pixel lens 700 due to oxygen and/or moisture can be prevented or at least reduced by the lens passivation layer 800.

The lower passivation layer 810 and the upper passivation layer 820 can include an insulating material. The lower passivation layer 810 and the upper passivation layer 820 can include a material capable blocking or delaying the penetration of oxygen and moisture. For example, the lower passivation layer 810 and the upper passivation layer 820 can include silicon nitride (SiNx). The lower passivation layer 810 and the upper passivation layer 820 can have a smaller thickness than the optical insulating layer 600 and the lens planarization layer 750. For example, each of the lower passivation layer 810 and the upper passivation layer 820 can be a linear insulating layer having a constant thickness. The upper passivation layer 820 can include a same material as the lower passivation layer 810. For example, a thickness of the upper passivation layer 820 can be a same as a thickness of the lower passivation layer 810.

The lower surface of each pixel lens 700 can be in direct contact with the lower passivation layer 810. The lower passivation layer 810 can extend beyond each pixel lens 700. For example, the lower passivation layer 810 can extend along an upper surface of the upper barrier pattern 520 opposite to the device substrate 100 and the upper surface of the optical insulating layer 600. The upper surface of the upper barrier pattern 520 and the upper surface of the optical insulating layer 600 can be in direct contact with the lower passivation layer 810.

A surface of each pixel lens having a convex shape can be in direct contact with the upper passivation layer 820. An upper surface and lower surface of the portion of the upper passivation layer 820 that overlap the curved upper surface (e.g., convex shape) of the pixel lens 700 each have a shape that corresponds to (e.g., matches) curved upper surface of the pixel lens 700, such as the convex shape. The upper passivation layer 820 can extend beyond each pixel lens 700. For example, the upper passivation layer 820 can extend along a surface of each pixel lens having a convex shape. A surface of the lens planarization layer 750 toward the device substrate 100 can be in direct contact with the upper passivation layer 820.

The upper passivation layer 820 can be in direct contact with the lower passivation layer 810 at the outside of each pixel lens 700. For example, the lower passivation layer 810 can be in direct contact with the upper barrier pattern 520 and the upper passivation layer 820 at a position where the pixel lens 700 is not between the lower passivation layer 810 and the upper passivation layer 820. Thus, in the display apparatus according to the embodiment of the present disclosure, oxygen and/or moisture contained in each pixel lens 700 cannot move to the optical insulating layer 600 and/or the lens planarization layer 750. In general, color sense of each pixel lens 700 made of a polymer material can be different according to the content of oxygen and moisture contained in the corresponding pixel lens 700. For example, the pixel lens denatured by the penetration of the external oxygen and/or moisture can have a color sense different from the pixel lens which is not denatured by the external oxygen and moisture. That is, in the display apparatus according to the embodiment of the present disclosure, the deviation of color sense due to the difference in the content of oxygen and/or moisture contained in each pixel lens 700 can be prevented by the lens passivation layer 800.

The upper passivation layer 820 can have a refractive index that is less than or equal to each pixel lens 700. For example, a refractive index of the lens planarization layer 750 can be smaller than a refractive index of the upper passivation layer 820. Thus, in the display apparatus according to the embodiment of the present disclosure, the light passing through each pixel lens 700 cannot be reflected toward the device substrate 100 at a boundary between the corresponding pixel lens 700 and the upper passivation layer 820 and/or a boundary between the upper passivation layer 820 and the lens planarization layer 750. That is, in the display apparatus according to the embodiment of the present disclosure, the loss of the light due to the different in refractive indexes can be prevented. Therefore, in the display apparatus according to the embodiment of the present disclosure, the light extraction efficiency can be improved.

Accordingly, the display apparatus according to the embodiment of the present disclosure can include the optical insulating layer 600 on the light-emitting devices 300, the pixel lenses 700 on the optical insulating layer 600, the lens planarization layer 750 on the pixel lenses 700, and the lens passivation layer 800 surrounding each pixel lens 700 between the optical insulating layer 600 and the lens planarization layer 750, wherein the lens passivation layer 800 can have the oxygen gas transmission rate (OTR) and the water vapor transmission rate (WVTR) smaller than the optical insulating layer 600 and the lens planarization layer 750. Thus, in the display apparatus according to the embodiment of the present disclosure, the denaturation of each pixel lens 700 due to the penetration of the external oxygen and/or the external moisture can be prevented. And, in the display apparatus according to the embodiment of the present disclosure, the deviation in the color sense of each pixel lens 700 due to the difference in the content of oxygen and/or moisture can be prevented. Therefore, in the display apparatus according to the embodiment of the present disclosure, the deterioration in the quality of the image due to oxygen and moisture can be prevented.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor pattern. The third gate electrode of each pixel area PA can be electrically connected to the gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

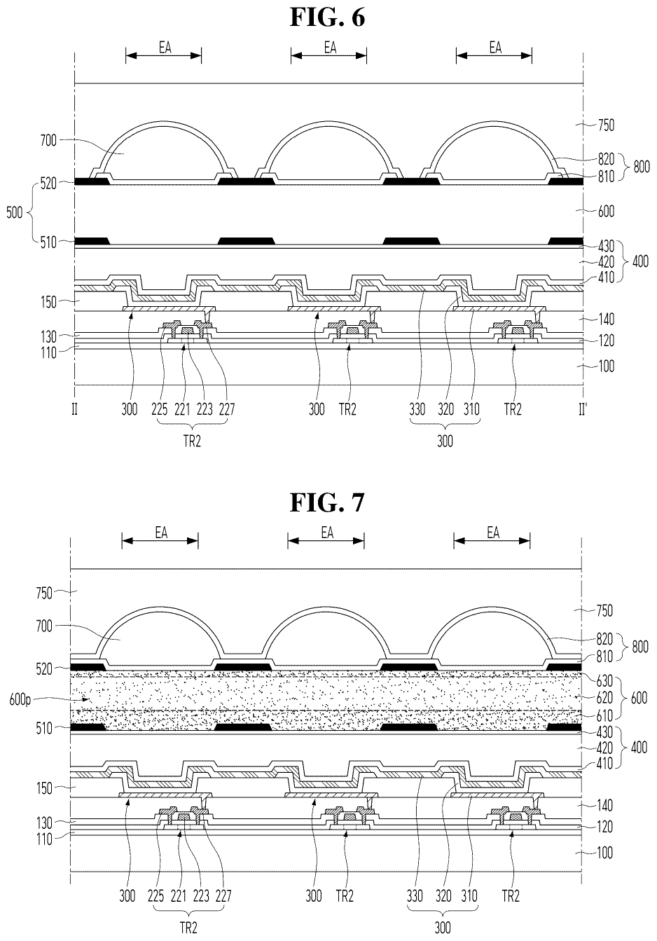

The display apparatus according to the embodiment of the present disclosure is described that the lower passivation layer 810 and the upper passivation layer 820 surrounding each pixel lens 700 can be in direct contact with the lower passivation layer 810 and the upper passivation layer 820 surrounding adjacent pixel lens 700. However, in the display apparatus according to another embodiment of the present disclosure, a portion of the lower passivation layer 810 and a portion of the upper passivation layer 820, which are disposed outside each pixel lens 700 can be removed. For example, in the display apparatus according to another embodiment of the present disclosure, the lens passivation layer 800 surrounding each pixel lens 700 can be spaced apart from the lens passivation layer 800 surrounding adjacent pixel lens 700, as shown in FIGS. 5 and 6. Thus, in the display apparatus according to another embodiment of the present disclosure, the movement of oxygen and/or moisture through a boundary between the lower passivation layer 810 and the upper passivation layer 820 can be blocked. Therefore, in the display apparatus according to another embodiment of the present disclosure, the deviation in the color sense of each pixel lens 700 due to the difference in the content of oxygen and/or moisture can be effectively prevented.

The upper passivation layer 820 covering a surface of each pixel lens 700 having a convex shape can cover an end of the lower passivation layer 810 being in contact with the lower surface of the corresponding pixel lens 700. Thus, in the display apparatus according to another embodiment of the present disclosure, the denaturation of each pixel lens 700 due to oxygen and/or moisture penetrated through a boundary between the lower passivation layer 810 and the upper passivation layer 820 can be prevented. Therefore, in the display apparatus according to another embodiment of the present disclosure, the deterioration in the quality of the image due to oxygen and moisture can be effectively prevented.

An end of the lens passivation layer 800 surrounding each pixel lens 700 can be disposed on the upper surface of the upper barrier pattern 520. For example, the lens planarization layer 750 can be in direct contact with the upper surface of the upper barrier pattern 520 at the outside of the upper passivation layer 820. Thus, in the display apparatus according to another embodiment of the present disclosure, the adhesive strength between the upper barrier pattern 520 and the lower passivation layer 810 can be supplemented by the lens planarization layer 750. Therefore, in the display apparatus according to another embodiment of the present disclosure, the degree of freedom in the material of the lower passivation layer 810 can be improved. For example, in the display apparatus according to another embodiment of the present disclosure, the peeling of the lens passivation layer 800 due to low adhesive strength between the upper barrier pattern 520 and the lower passivation layer 810 can be prevented.

In the display apparatus according to another embodiment of the present disclosure, the optical insulating layer 600 can be an organic insulating layer made of an organic insulating material. For example, in the display apparatus according to another embodiment of the present disclosure, a process of forming the optical insulating layer 600 can include a curing process using ultraviolet (UV). In the display apparatus according to another embodiment of the present disclosure, a UV absorbent 600p can dispersed in the optical insulating layer 600. The content of the UV absorbent 600p dispersed in the optical insulating layer 600 can be different in a thickness direction of the optical insulating layer 600. For example, in the display apparatus according to another embodiment of the present disclosure, the optical insulating layer 600 can include a lower end portion 610 disposed close to the encapsulation structure 400, a central portion 620 disposed on the lower end portion 610 and farther from the encapsulation structure 400 than the lower end portion 610, and a surface layer portion 630 disposed on the central portion 620 such that the central portion 620 is between the surface layer portion 630 and the lower end portion 610. The content of the UV absorbent 600p dispersed in the lower end portion 610 of the optical insulating layer 600 can be greater than the content of the UV absorbent 600p dispersed in the central portion 620 of the optical insulating layer 600, and the content of the UV absorbent 600p dispersed in the surface layer portion 630 of the optical insulating layer 600 including the upper surface of the optical insulating layer 600 can have a greater content than the UV absorbent 600p dispersed in the central portion 620 of the optical insulating layer 600, as shown in FIG. 7.

In general, the intensity and the amount of UV irradiated on the upper surface of the optical insulating layer 600 for a curing process can decrease toward the device substrate 100. For example, the intensity and the amount of UV irradiated to the lower end portion 610 of the optical insulating layer 600 can be smaller than the intensity and the amount of UV irradiated to the central portion 620 of the optical insulating layer 600. Thus, in the display apparatus according to another embodiment of the present disclosure, the lower end portion 610 of the optical insulating layer 600 can be sufficiently cured by a difference in the content of the UV absorbent 600p between the lower end portion 610 and the central portion 620 of the optical insulating layer 600. An uncured region of an organic insulating layer can have a lower adhesive strength than a cured region of an organic insulating layer. That is, in the display apparatus according to another embodiment of the present disclosure, the peeling of the optical insulating layer 600 from the encapsulation structure 400 due to unstable curing of the lower end portion 610 of the optical insulating layer 600 can be prevented. A transmittance of an uncured region of an organic insulating layer can be different from a transmittance of a cured region of an organic insulating layer. Therefore, in the display apparatus according to another embodiment of the present disclosure, the difference in luminance of the light emitted from the light-emitting device 300 of each pixel area PA due to unstable curing of the lower end portion 610 of the optical insulating layer 600 can be prevented.

In a process of curing an organic insulating layer using UV irradiated on an upper surface of the organic insulating layer, some part of the organic insulating layer disposed close to the upper surface of the organic insulating layer cannot be partially cured due to the interference of oxygen or the like. Thus, in the display apparatus according to another embodiment of the present disclosure, the surface layer portion 630 of the optical insulating layer 600 having a larger content of the UV absorbent 600p than the central portion 620 of the optical insulating layer 600 can be stably cured. And, in the display apparatus according to another embodiment of the present disclosure, the decrease in the adhesive strength between the optical insulating layer 600 and the lens passivation layer 800 due to an uncured part of the surface layer portion 630 of the optical insulating layer 600 can be prevented. An uncured part of the surface layer portion 630 of the optical insulating layer 600 can be removed by a process of forming the upper barrier pattern 520. That is, in the display apparatus according to another embodiment of the present disclosure, the occurrence of under-cut due to the removal of an uncured part of the surface layer portion 630 can be prevented. Therefore, in the display apparatus according to another embodiment of the present disclosure, the decrease in the quality of the image due to the partially peeling of the pixel lenses 700 can be prevented.

In the display apparatus according to another embodiment of the present disclosure, an antioxidant can be dispersed in the optical insulating layer 600 and the lens planarization layer 750. Thus, in the display apparatus according to another embodiment of the present disclosure, oxygen and moisture moving through the optical insulating layer 600 and/or the lens planarization layer 750 can react with the antioxidant. That is, in the display apparatus according to another embodiment of the present disclosure, oxygen and/or moisture penetrating each pixel lens 700 through the optical insulating layer 600 and the lens planarization layer 750 can be significantly reduced. Therefore, in the display apparatus according to another embodiment of the present disclosure, the denaturation of each pixel lens 700 due to oxygen and moisture can be effectively prevented.

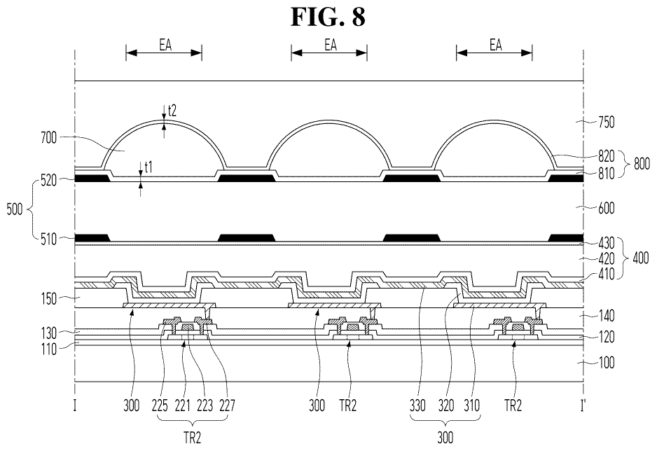

The display apparatus according to the embodiment of the present disclosure is described that the refractive index of the upper passivation layer 820 is lower than the refractive index of each pixel lens 700. However, in the display apparatus according to another embodiment of the present disclosure, each of the pixel lenses 700 can have a refractive index larger than the lens planarization layer 750, the refractive index of the upper passivation layer 820 can be larger than the refractive index of each pixel lens 700, and the upper passivation layer 820 can have a relative small thickness. For example, in the display apparatus according to another embodiment of the present disclosure, a thickness t2 of the upper passivation layer 820 can be smaller than a thickness t1 of the lower passivation layer 810, as shown in FIG. 8. Thus, in the display apparatus according to another embodiment of the present disclosure, the degree of freedom in the material of the upper passivation layer 820, and the loss of the light due to the refractive index of the upper passivation layer 820 can be reduced.

The lower passivation layer 810 can include a different material from the upper passivation layer 820. For example, a refractive index of the lower passivation layer 810 can be between a refractive index of the optical insulating layer 600 and a refractive index of each pixel lens 700. Thus, in the display apparatus according to another embodiment of the present disclosure, the loss of the light due to difference in the refractive index can be minimized.

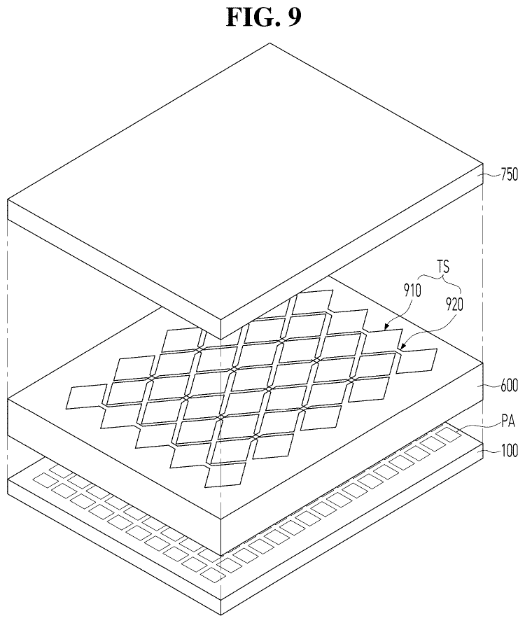

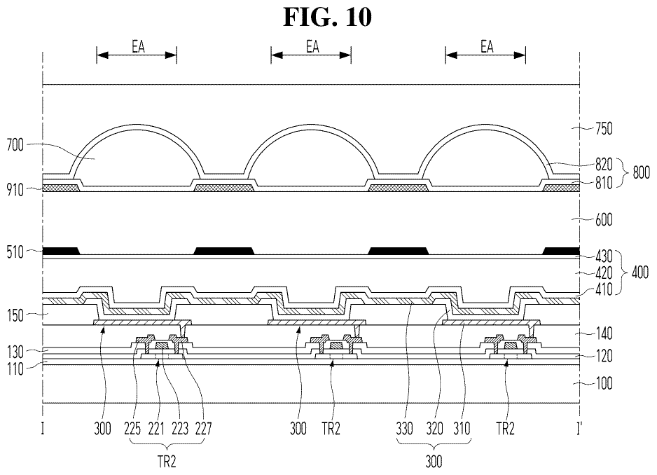

The display apparatus according to the embodiment of the present disclosure is described that the upper barrier pattern 520 includes a same material as the lower barrier pattern 510. However, in the display apparatus according to another embodiment of the present disclosure, that the upper barrier pattern 520 can include a different material from the lower barrier pattern 510. For example, in the display apparatus according to another embodiment of the present disclosure, a touch sensor TS for sensing a touch of the user or a tool can be disposed between the optical insulating layer 600 and the lens planarization layer 750, as shown in FIGS. 9 and 10.

The touch sensor TS can include touch electrodes 910 and bridge electrodes 920 connecting between the touch electrodes 910. The touch electrodes 910 and the bridge electrodes 920 can include a conductive material. The touch electrodes 910 and the bridge electrodes 920 can include a material capable of blocking light. For example, the touch electrodes 910 and the bridge electrodes 920 can include a metal. At least one of the bridge electrodes 920 can include a different material from the touch electrodes 910. For example, at least one of the bridge electrodes 920 can be disposed on a different layer from the touch electrodes 910.

A lower surface of each touch electrode 910 toward the device substrate 100 can be in direct contact with the upper surface of the optical insulating layer 600. For example, the touch electrodes 910 can be disposed between the optical insulating layer 600 and the lens passivation layer 800. The touch electrodes 910 can be disposed outside the emission area EA defined in each pixel area PA. For example, the touch electrodes 910 can be disposed within the non-emission area. The touch electrodes 910 can overlap the lower barrier pattern 510. The traveling direction of the light emitted from the emission area EA of each pixel area PA can be limited by the touch electrodes 910. For example, in the display apparatus according to another embodiment of the present disclosure, the touch electrodes 910 can function as the upper barrier pattern. That is, in the display apparatus according to another embodiment of the present disclosure, a process of forming the upper barrier pattern can be omitted. Therefore, in the display apparatus according to another embodiment of the present disclosure, the process efficiency can be improved.

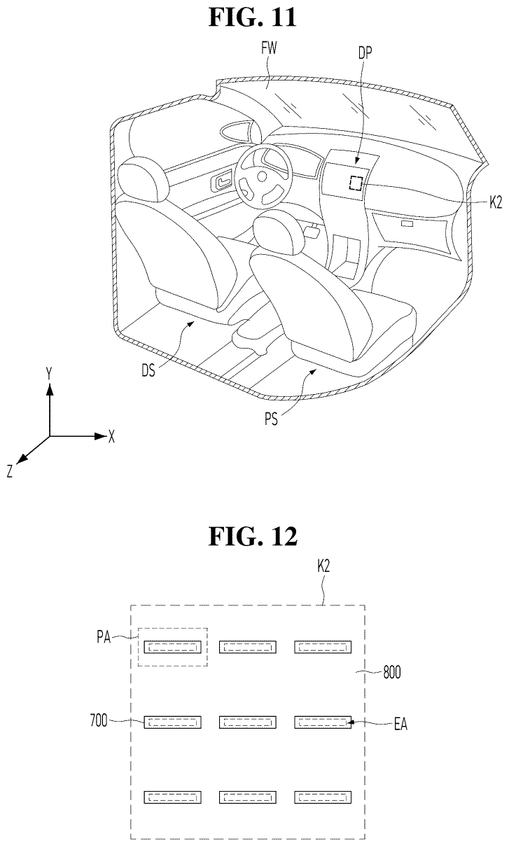

The display apparatus according to another embodiment of the present disclosure can include the display panel DP installed inside a car. For example, in the display apparatus according to another embodiment of the present disclosure, the display panel DP can be disposed between a driver seat DS and a passenger seat PS, as shown in FIGS. 11 and 12. The image realized by the display panel DP can be shared with a driver sitting in the driver seat DS and a passenger sitting in the passenger seat PS. The image realized by the display panel DP cannot be reflected by a front wind-shield (FW) of the car. For example, the emission area EA of each pixel area PA and each pixel lens 700 can have a shape of a bar extending in a first direction X. Herein, the first direction X is a direction toward the passenger seat PS from the driver seat DS. The pixel areas PA can be disposed side by side in the first direction X and a second direction Y perpendicular to the first direction X. For example, the front wind-shield FW of the car can be disposed side by side with the display panel DP. A third direction perpendicular to the first direction X and the second direction Y can be a direction toward the driver and the passenger from the display panel DP. Thus, in the display apparatus according to another embodiment of the present disclosure, the image realized by the emission area EA of each pixel area PA and each pixel lens 700 can have a wide viewing angle in the first direction X.

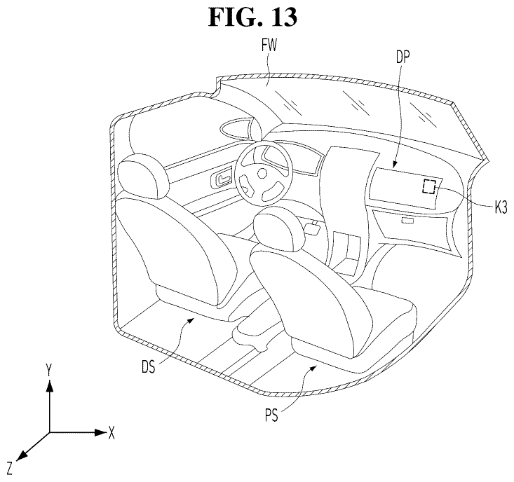

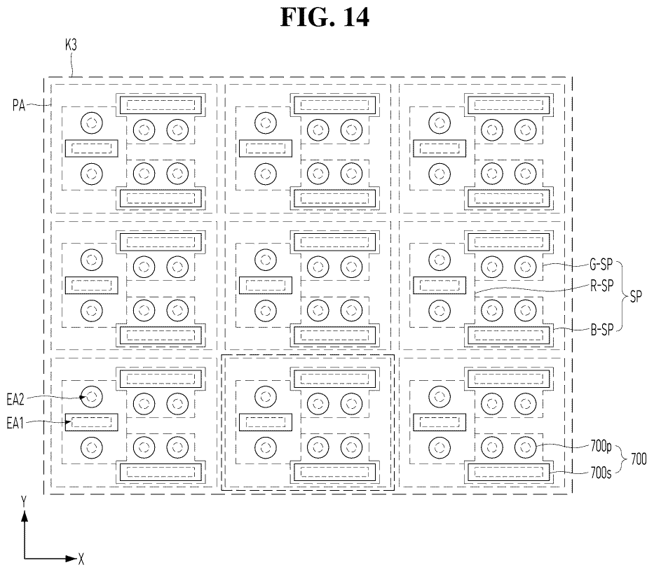

In the display apparatus according to another embodiment of the present disclosure, the image realized by the display panel DP can't be recognized by the driver sitting in the driver seat DS, optionally. For example, in the display apparatus according to another embodiment of the present disclosure, the display panel DP installed in front of the passenger seat PS of the car can realize one of a first image shared with the driver sitting in the driver seat DS and the passenger sitting in the passenger seat PS and a second image that is not recognized by the driver, as shown in FIGS. 13 and 14. Thus, in the display apparatus according to another embodiment of the present disclosure, accidents due to gaze dispersion of the driver can be prevent, while the car is in the driving.

A plurality of sub-pixels SP can be disposed within each pixel area PA. For example, a red sub-pixel R-SP realizing a red color, a green sub-pixel G-SP realizing a green color and a blue sub-pixel B-SP realizing a blue color can be disposed within each pixel area PA. A first emission area EA1 and a second emission area EA2 can be defined in each sub-pixel SP. The number of the second emission area EA2 defined in each sub-pixel SP can be different from the number of the first emission area EA1 defined in the corresponding sub-pixel SP. For example, a single first emission area EA1 and two second emission areas EA2 can be defined in each sub-pixel SP.

A plane of the second emission area EA2 can be different from a plane of the first emission area EA1. For example, the first emission area EA1 can have a planar shape of a bar extending in the first direction, and a plane of the second emission area EA2 can have a circular shape. The pixel lenses 700 overlapping with the emission areas EA1 and EA2 of each sub-pixel SP can include a first pixel lens 700s having a planar shape corresponding to the first emission area EA1 of each sub-pixel SP and a second pixel lens 700p have a planar shape corresponding to the second emission area EA2 of each sub-pixel SP. The first emission area EA1 of each sub-pixel SP and the first pixel lens 700s can realize an image having a wider viewing angle in the first direction X than the second emission area EA2 of each sub-pixel SP and the second pixel lens 700p. Thus, in the display apparatus according to another embodiment of the present disclosure, one of the first image by the first emission area EA1 of each sub-pixel SP and the first pixel lens 700s and the second image by the second emission area EA1 of each sub-pixel SP and the second pixel lens 700p can be provided. That is, in the display apparatus according to another embodiment of the present disclosure, the first image having a relative wide viewing angle and the second image having a relative narrow viewing angle can be optionally realized. Therefore, in the display apparatus according to another embodiment of the present disclosure, the difference in color sense of the images having various viewing angles can be minimized.

In the result, the display apparatus according to the embodiments of the present disclosure can comprise the optical insulating layer on the light-emitting device, the lens planarization layer on the optical insulating layer, the pixel lens between the optical insulating layer and the lens planarization layer and the lens passivation layer surrounding the pixel lens, wherein the pixel lens can overlap the light-emitting device, and wherein oxygen and/or moisture moving through the optical insulating layer and the lens planarization layer can be blocked or delayed by the lens passivation layer. Thus, in the display apparatus according to the embodiments of the present disclosure, the denaturation of the pixel lens due to the oxygen and/or moisture can be prevented. Thereby, in the display apparatus according to the embodiments of the present disclosure, the decrease in the quality of the image provided to the user due to oxygen and moisture can be prevented. And, in the display apparatus according to the embodiments of the present disclosure, the production energy can be reduced by the process optimization.

In one embodiment, a display apparatus comprises: a light-emitting device on an emission area of a device substrate; an optical insulating layer on the light-emitting device, the optical insulating layer extending beyond the emission area; a lens passivation layer including a lower passivation layer on the optical insulating layer and an upper passivation layer on the lower passivation layer; a pixel lens between the lower passivation layer and the upper passivation layer of the lens passivation layer, the pixel lens overlapping with the emission area; and a lens planarization layer on the upper passivation layer of the lens passivation layer, the lens planarization layer including a region overlapping with the emission area, wherein the lens passivation layer has an oxygen gas transmission rate (OTR) that is less than an OTR of the optical insulating layer and an OTR of the lens planarization layer.

In one embodiment, a water vapor transmission rate (WVTR) of the lens passivation layer is less than a WVTR of the optical insulating layer and a WVTR of the lens planarization layer.

In one embodiment, a portion of the upper passivation layer is in contact with a portion of the lower passivation layer at a position where the pixel lens is not between the lower passivation layer and the upper passivation layer.

In one embodiment, the upper passivation layer includes a material that is different from a material of the lower passivation layer.

In one embodiment, the pixel lens has a refractive index that is less than a refractive index of the upper passivation layer, wherein a refractive index of the lens planarization layer is less than the refractive index of the pixel lens, and wherein the upper passivation layer has a thickness that is less than a thickness of the lens planarization layer.

In one embodiment, a thickness of the upper passivation layer is less than a thickness of the lower passivation layer.

In one embodiment, the display apparatus further comprises: an ultraviolet (UV) absorbent dispersed in the optical insulating layer, wherein the optical insulating layer includes a lower end portion disposed, a central portion disposed on the lower end portion and farther from the light-emitting device than the lower end portion, and a surface layer portion on the central portion such that the central portion is between the lower end portion and the surface layer portion, wherein the surface layer portion of the optical insulating layer includes an upper surface of the optical insulating layer toward the lens passivation layer, and wherein a content of the UV absorbent in the surface layer portion of the optical insulating layer is greater than a content of the UV absorbent in the central portion of the optical insulating layer.

In one embodiment, a content of the UV absorbent in the lower end portion of the optical insulating layer is greater than the content of the UV absorbent in the central portion of the optical insulating layer, and wherein a thickness of the surface layer portion is less than a thickness of the lower end portion and a thickness of the central portion.

In one embodiment, a display apparatus comprises: a first light-emitting device on a first emission area of a device substrate; a second light-emitting device on a second emission area of the device substrate; an optical insulating layer on the first light-emitting device and the second light-emitting device; a first pixel lens on the optical insulating layer, the first pixel lens overlapping with the first emission area; a first lens passivation layer on the optical insulating layer, the first lens passivation layer surrounding the first pixel lens; a second pixel lens on the optical insulating layer, the second pixel lens overlapping with the second emission area; a second lens passivation layer on the optical insulating layer, the second lens passivation layer surrounding the second pixel lens; and a lens planarization layer on the first lens passivation layer and the second lens passivation layer, the lens planarization layer overlapping with the first emission area and the second emission area, wherein the first lens passivation layer and the second lens passivation layer have a water vapor transmission rate (WVTR) that is less than a WVTR of the optical insulating layer and a WVTR of the lens planarization layer.

In one embodiment, the second lens passivation layer has a stacked structure that is a same as the first lens passivation layer.

In one embodiment, the second lens passivation layer is spaced apart from the first lens passivation layer at a location between the first emission area and the second emission area.

In one embodiment, each of the first lens passivation layer and the second lens passivation layer has a stacked structure that comprises a lower passivation layer and an upper passivation layer on the lower passivation layer, and wherein an end portion of the lower passivation layer is covered by the upper passivation layer.

In one embodiment, the display apparatus further comprises: an upper barrier pattern that is non-overlapping with the first emission area and the second emission area, the upper barrier pattern between the optical insulating layer and the lens planarization layer, wherein an end portion of the first lens passivation layer and an end of the second lens passivation layer overlap the upper barrier pattern.

In one embodiment, the lens planarization layer is in contact with the upper barrier pattern at a location between the first lens passivation layer and the second lens passivation layer.

In one embodiment, the display apparatus further comprises: an antioxidant dispersed in the optical insulating layer and the lens planarization layer.

In one embodiment, a display device comprises: a substrate including an emission area; a thin film transistor on the substrate; a light emitting device that is connected to the thin film transistor, the light emitting device in the emission area; a first lens passivation layer; a pixel lens on the first lens passivation layer and overlapping the light emitting device in the emission area, pixel lens having a curved upper surface; and a second lens passivation layer that covers the curved upper surface of the pixel lens, the second lens passivation layer having an upper surface and a lower surface that each have a curved shape that corresponds to the curved upper surface of the pixel lens.

In one embodiment, the display device further comprises: an optical insulating layer between the light emitting device and the first lens passivation layer; and a lens planarization layer on the second lens passivation layer.

In one embodiment, the first lens passivation layer and the second lens passivation layer have an oxygen gas transmission rate (OTR) that is less than an OTR of the optical insulating layer and an OTR of the lens planarization layer.

In one embodiment, the first lens passivation layer and the second lens passivation layer have a water vapor transmission rate (WVTR) that is less than a WVTR of the optical insulating layer and a WVTR of the lens planarization layer.

In one embodiment, the lower surface of the second lens passivation layer is in direct contact with the curved upper surface of the pixel lens.

In one embodiment, the first lens passivation layer is in direct contact with a lower surface of the pixel lens.

In one embodiment, the pixel lens has a refractive index that is less than a refractive index of the second lens passivation layer, wherein a refractive index of the lens planarization layer is less than the refractive index of the pixel lens, and wherein the second lens passivation layer has a thickness that is less than a thickness of the lens planarization layer.

In one embodiment, a thickness of the second lens passivation layer is less than a thickness of the first lens passivation layer.

What is claimed is:

1. A display apparatus comprising:
a light-emitting device on an emission area of a device substrate;
an optical insulating layer on the light-emitting device, the optical insulating layer extending beyond the emission area;
a lens passivation layer including a lower passivation layer on the optical insulating layer and an upper passivation layer on the lower passivation layer;
a pixel lens between the lower passivation layer and the upper passivation layer of the lens passivation layer, the pixel lens overlapping with the emission area; and
a lens planarization layer on the upper passivation layer of the lens passivation layer, the lens planarization layer including a region overlapping with the emission area,
wherein the lens passivation layer has an oxygen gas transmission rate (OTR) that is less than an OTR of the optical insulating layer and an OTR of the lens planarization layer.

2. The display apparatus according to claim 1, wherein a water vapor transmission rate (WVTR) of the lens passivation layer is less than a WVTR of the optical insulating layer and a WVTR of the lens planarization layer.

3. The display apparatus according to claim 1, wherein a portion of the upper passivation layer is in contact with a portion of the lower passivation layer at a position where the pixel lens is not between the lower passivation layer and the upper passivation layer.

4. The display apparatus according to claim 1, wherein the upper passivation layer includes a material that is different from a material of the lower passivation layer.

5. The display apparatus according to claim 1, wherein the pixel lens has a refractive index that is less than a refractive index of the upper passivation layer,
wherein a refractive index of the lens planarization layer is less than the refractive index of the pixel lens, and
wherein the upper passivation layer has a thickness that is less than a thickness of the lens planarization layer.

6. The display apparatus according to claim 5, wherein a thickness of the upper passivation layer is less than a thickness of the lower passivation layer.

7. The display apparatus according to claim 1, further comprising:
an ultraviolet (UV) absorbent dispersed in the optical insulating layer,
wherein the optical insulating layer includes a lower end portion disposed, a central portion disposed on the lower end portion and farther from the light-emitting device than the lower end portion, and a surface layer portion on the central portion such that the central portion is between the lower end portion and the surface layer portion,
wherein the surface layer portion of the optical insulating layer includes an upper surface of the optical insulating layer toward the lens passivation layer, and
wherein a content of the UV absorbent in the surface layer portion of the optical insulating layer is greater than a content of the UV absorbent in the central portion of the optical insulating layer.

8. The display apparatus according to claim 7, wherein a content of the UV absorbent in the lower end portion of the optical insulating layer is greater than the content of the UV absorbent in the central portion of the optical insulating layer, and
wherein a thickness of the surface layer portion is less than a thickness of the lower end portion and a thickness of the central portion.

9. A display apparatus, comprising:
a first light-emitting device on a first emission area of a device substrate;
a second light-emitting device on a second emission area of the device substrate;
an optical insulating layer on the first light-emitting device and the second light-emitting device;
a first pixel lens on the optical insulating layer, the first pixel lens overlapping with the first emission area;
a first lens passivation layer on the optical insulating layer, the first lens passivation layer surrounding the first pixel lens;
a second pixel lens on the optical insulating layer, the second pixel lens overlapping with the second emission area;
a second lens passivation layer on the optical insulating layer, the second lens passivation layer surrounding the second pixel lens; and
a lens planarization layer on the first lens passivation layer and the second lens passivation layer, the lens planarization layer overlapping with the first emission area and the second emission area,
wherein the first lens passivation layer and the second lens passivation layer have a water vapor transmission rate (WVTR) that is less than a WVTR of the optical insulating layer and a WVTR of the lens planarization layer.

10. The display apparatus according to claim 9, wherein the second lens passivation layer has a stacked structure that is a same as the first lens passivation layer.

11. The display apparatus according to claim 9, wherein the second lens passivation layer is spaced apart from the first lens passivation layer at a location between the first emission area and the second emission area.

12. The display apparatus according to claim 11, wherein each of the first lens passivation layer and the second lens passivation layer has a stacked structure that comprises a lower passivation layer and an upper passivation layer on the lower passivation layer, and
wherein an end portion of the lower passivation layer is covered by the upper passivation layer.

13. The display apparatus according to claim 11, further comprising:
an upper barrier pattern that is non-overlapping with the first emission area and the second emission area, the upper barrier pattern between the optical insulating layer and the lens planarization layer,
wherein an end portion of the first lens passivation layer and an end of the second lens passivation layer overlap the upper barrier pattern.

14. The display apparatus according to claim 13, wherein the lens planarization layer is in contact with the upper barrier pattern at a location between the first lens passivation layer and the second lens passivation layer.

15. The display apparatus according to claim 9, further comprising:
an antioxidant dispersed in the optical insulating layer and the lens planarization layer.

16. A display device comprising:
a substrate including an emission area;
a thin film transistor on the substrate;
a light emitting device that is connected to the thin film transistor, the light emitting device in the emission area;
a first lens passivation layer over the light emitting device;
a pixel lens on the first lens passivation layer and overlapping the light emitting device in the emission area, pixel lens having a curved upper surface; and
a second lens passivation layer that covers the curved upper surface of the pixel lens, the second lens passivation layer having an upper surface and a lower surface that each have a curved shape that corresponds to the curved upper surface of the pixel lens,
wherein a movement of oxygen and/or moisture contained in the pixel lens surrounded by the first lens passivation layer and the second lens passivation layer is blocked.

17. The display device of claim 16, further comprising:
an optical insulating layer between the light emitting device and the first lens passivation layer; and
a lens planarization layer on the second lens passivation layer,
wherein the first lens passivation layer and the second lens passivation layer have an oxygen gas transmission rate (OTR) that is less than an OTR of the optical insulating layer and an OTR of the lens planarization layer.

18. The display device of claim 16, further comprising:
an optical insulating layer between the light emitting device and the first lens passivation layer; and
a lens planarization layer on the second lens passivation layer,
wherein the first lens passivation layer and the second lens passivation layer have a water vapor transmission rate (WVTR) that is less than a WVTR of the optical insulating layer and a WVTR of the lens planarization layer.

19. The display device of claim 16, wherein the lower surface of the second lens passivation layer is in direct contact with the curved upper surface of the pixel lens.

20. The display device of claim 16, wherein the first lens passivation layer is in direct contact with a lower surface of the pixel lens.
